(19) United States
(12) Patent Application Publication
(10) Pub. No.: US 2011/0126902 A1
(43) Pub. Date: Jun. 2, 2011

(54) APPARATUS AND METHOD FOR MANUFACTURING THIN FILM SOLAR CELL, AND THIN FILM SOLAR CELL

(75) Inventors: Masashi Kikuchi, Chigasaki-shi (JP); Atsushi Masuda, Tsukuba-shi (JP)

(73) Assignees: ULVAC, INC., Kanagawa (JP); NATIONAL INSTITUTE OF ADVANCED INDUSTRIAL SCEINCE, IBARAKI-KEN (JP)

(21) Appl. No.: 13/055,402

(22) PCT Filed: Jul. 24, 2009
(86) PCT No.: PCT/JP2009/063297

§ 371 Date: Jan. 21, 2011

(30) Foreign Application Priority Data
Jul. 25, 2008 (JP) 2008-192490

(51) Int. Cl. H01L 31/0216; H01L 31/20; H01L 31/18; B05C 5/00

(52) U.S. Cl. 136/256; 438/96; 438/98; 118/620; 257/E31.124; 257/E31.003

(57) ABSTRACT

An apparatus for manufacturing a thin film solar cell that increase homogeneity in film characteristics. In a process of conveying a substrate from one roll to another roll, a power generation layer, which is a laminated body of a plurality of semiconductor layers, is formed in a plurality of film formation compartments partitioned along a conveying direction between the roll pair. A plurality of flat application electrodes are laid out in the conveying direction facing toward the substrate in each film formation compartment. Each flat application electrode includes a power supply terminal supplied with high frequency power in a VHF band. When the wavelength of the high frequency power is represented by λ, the distance between an edge of the flat application electrode and the power supply terminal is set to be shorter than λ/4 in a direction orthogonal to the conveying direction.

### PRIORITY CLAIM

The present application is a National Phase entry of PCT Application No. PCT/JP2009/063297, filed Jul. 24, 2009, which claims priority from Japanese Patent Application Number 2008-192490, filed Jul. 25, 2008, the disclosures of which are hereby incorporated by reference herein in their entirety.

### TECHNICAL FIELD

The present invention relates to an apparatus for manufacturing a thin film solar cell by performing a film formation process on a substrate while unwinding the substrate from a roll and a method for manufacturing a thin film solar cell.

### BACKGROUND ART

Amorphous silicon (a-Si) solar cells drastically reduce the used amount of silicon, which is a raw material, in comparison to bulk type Si solar cells. Thus, amorphous silicon solar cells have become noteworthy since they resolve the problem of insufficient raw materials. Further, Si microcrystal thin film solar cells, which use microcrystal Si films (nc-Si) in lieu of a-Si films serving as power generation layers, are known as one type of such thin film solar cells.

One known method for manufacturing the thin film solar cell described above is the so-called roll-to-roll processing (refer to patent literature 1) that forms a power generation layer on a moving substrate, while unwinding one roll of a substrate and winding the substrate into another roll. In another manufacturing method that uses a substrate wound into a roll, whenever a film formation region of a substrate is positioned in a film formation compartment, the unwinding of the substrate is temporarily stopped to perform a film formation process on the substrate. This is known as the so-called stepping roll processing (refer to patent literature 2). Generally, in a mass production manufacturing process, there is a strong demand for reduction in the cost required for conversion efficiency. Thus, there are high expectations for the roll-to-roll processing, which does not stop the unwinding of the substrate in the manufacturing process, and achieves higher productivity than the stepping roll process, which periodically stops the unwinding.
Patent Literature 1: Japanese Laid-Open Patent Publication No. 6-291349
Patent Literature 2: Japanese Laid-Open Patent Publication No. 11-288890

The power generation layer of the thin film solar cell described above includes a plurality of different superimposed semiconductor layers of a p type, i type, n type, and the like. In the roll-to-roll processing and the stepping roll processing, the substrate, which is moved by rotating the roll, sequentially passes through a plurality of film formation compartments to form semiconductor layers. In this case, for semiconductor layers of which film formation speed is slow or semiconductor layers of which film thickness is large, the film formation time must be prolonged in correspondence with the slow film formation speed or large film thickness. In the roll-to-roll processing or stepping processing, the conveying timing of the substrate is synchronized in each film formation compartments. Thus, when selectively prolonging the film formation time for a single semiconductor layer, the film formation compartment for forming the semiconductor layer must be elongated in the conveying direction.

For example, when using an apparatus of which conveying speed is 0.3 m/sec to form a p layer having a thickness of 20 nm at a film formation speed of 2 nm/sec, the film formation compartment would only require 3 m (20/2×0.3) in the conveying direction. In contrast, when using the same apparatus to form an i layer having thickness of 150 nm at the same film formation speed, the film formation compartment would require as much as 22.5 m (150/2×0.3) in the conveying direction.

When a film formation compartment is elongated as described above, that is, when elongating an electrode for generating plasma, the wavelength of the high frequency wave provided to the electrode is significantly shorter than the electrode size. This forms a standing wave on the electrode. As a result, such a standing wave would bias the voltage distribution and make it difficult to obtain homogeneous plasma. This would lead to each semiconductor layer having heterogeneous film characteristics.

Accordingly, it is an object of the present invention to provide an apparatus for manufacturing a thin film solar cell that improves the homogeneity of film characteristics when performing a film formation process on a substrate while unwinding the substrate from a roll, a method for manufacturing the thin film solar cell, and the thin film solar cell.

### SUMMARY OF THE INVENTION

An apparatus for manufacturing a thin film solar cell according to the present invention includes a substrate conveying unit including a pair of rolls arranged in a vacuum tank, in which the pair of rolls are rotated to convey a substrate from one of the rolls to the other one of the rolls. A power generation layer formation unit includes a plurality of film formation compartments partitioned along a conveying direction of the substrate between the pair of rolls. Each of the plurality of film formation compartments form a semiconductor layer on the substrate to form a power generation layer that is a laminated body of a plurality of semiconductor layers. Each of the plurality of film formation compartments includes a plurality of flat application electrodes laid out along the conveying direction facing toward the substrate. The plurality of flat application electrodes each include a power supply terminal supplied with high frequency power in a VHF band. When the wavelength of the high frequency power is represented by λ, distance between an edge of the flat application electrode and the power supply terminal is shorter than λ/4 in a direction orthogonal to the conveying direction.

In this structure, the distance between an open end, which is the edge, of the flat application electrode and the power supply terminal is shorter than λ/4 in a direction orthogonal (vertical direction) to the conveying direction. This reduces the formation of a standing wave in the conveying direction at the flat application electrode when supplying the flat application electrode with high frequency power. A standing wave is more easily formed in the conveying direction than the vertical direction. However, a biased voltage distribution caused by a standing wave in the conveying direction, that is, a biased film formation speed in the conveying direction, is easily cancelled by conveying the substrate along the conveying direction. Accordingly, in each film formation compartment, the layout of the plurality of flat application electrodes in the conveying direction improves the homogeneity of the film characteristics regardless of the length in the conveying direction.

Additionally, the flat application electrode has a surface including a plurality of elliptic recesses, and a film formation portion opens in the bottom surface of each recess with a width that is smaller than the shorter side of the recess (i.e., a hole having a smaller diameter than the recess). In this case, film formation gas is ejected from the open part of the film formation gas supply portion in each recess. This homogeneously and stably generates high-density plasma in the plane of the high frequency electrode 32 and efficiently decomposes the film formation gas. Accordingly, the homogeneity of the film characteristics is increased, and high-speed film formation becomes possible.

Preferably, in the apparatus for manufacturing a thin film solar cell, the distance between the edge of the flat application electrode and the power supply terminal is shorter than λ/2 in the conveying direction.

In this structure, the standing waves formed in the conveying direction at the flat application electrode are reduced.

Preferably, in the apparatus for manufacturing a thin film solar cell, the distance between the edge of the flat application electrode and the power supply terminal is shorter than λ/4 in a plane of the flat application electrode that includes the conveying direction.

In this structure, it becomes difficult for a standing wave to be formed at the entire plane of the flat application electrode. Thus, in each film formation compartment, a biased voltage distribution caused by a standing wave is suppressed in a further ensured manner in a direction orthogonal to the conveying direction in addition to the conveying direction of the flat application electrode. This further improves the homogeneity in the film characteristics when performing a film formation process on a substrate wound around the roll.

Preferably, in the apparatus for manufacturing a thin film solar cell, the substrate conveying unit includes adjacent first and second roll pairs, each being the pair of rolls. The power generation layer formation unit includes a film formation compartment commonly shared by the first and second roll pairs. The commonly shared film formation compartment includes a flat ground electrode sandwiching the substrate with the plurality of flat application electrodes. The plurality of flat application electrodes or the flat ground electrode is arranged between a pair of substrates that are conveyed by the first and second rolls and shared by the two substrates.

In this structure, the flat application electrodes or the flat ground electrode perform a film formation process on two substrates. This simplifies the structure of the manufacturing apparatus from the aspect of improving the productivity of the thin film solar cell.

Preferably, in the apparatus for manufacturing a thin film solar cell, the plurality of film formation compartments are partitioned by gas curtains between the pair of rollers, and the substrate conveying unit continuously rotates the pair of rollers until the substrate on the one of the rollers is wound around the other one of the rolls.

In this structure, the space between the pair of rollers is partitioned in a non-contact manner. Thus, the film formation process may be performed continuously without stopping the unwinding of the substrate.

Preferably, the apparatus for manufacturing a thin film solar cell further includes a single flat plate ground electrode facing toward the plurality of flat application electrodes that are adjacent to one another in the conveying direction and commonly shared by the plurality of flat application electrodes.

In this structure, the flat ground electrode is commonly shared by the plurality of flat application electrodes. Thus, a further simple apparatus may be provided.

Preferably, in the apparatus for manufacturing a thin film solar cell, each of the plurality of film formation compartments includes a plurality of second flat application electrodes laid out along the conveying direction and facing toward the substrate, and the plurality of second flat application electrodes are spaced apart from the plurality of flat application electrodes in a direction orthogonal to the conveying direction.

In this structure, even when the width of each electrode is shortened in the vertical direction for a process that uses a shorter wavelength, two electrodes arranged in the vertical direction prevent the electrodes from being insufficient relative to the width of the substrate.

A method for manufacturing a thin film solar cell according to the present invention includes rotating a pair of rolls arranged in a vacuum tank to convey a substrate from one of the rolls to the other one of the rolls, and forming a power generation layer that is a laminated body of a plurality of semiconductor layers in a plurality of film formation compartments partitioned along a conveying direction of the substrate between the pair of rolls while conveying the substrate. The forming a power generation layer includes applying high frequency power in a VHF band to a plurality of flat application electrodes laid out along the conveying direction facing toward the substrate. The high frequency power is supplied to a power supply terminal arranged in each of the plurality of flat application electrodes. When the wavelength of the high frequency power is represented by λ, distance between an edge of the flat application electrode and the power supply terminal is set to be shorter than λ/4 in a direction orthogonal to the conveying direction.

In this method, the distance between an open end, which is the edge, of the flat application electrode and the power supply terminal is shorter than λ/4 in a direction orthogonal (vertical direction) to the conveying direction. This reduces the formation of a standing wave in the conveying direction at the flat application electrode when supplying the flat application electrode with high frequency power. A standing wave is more easily formed in the conveying direction than the vertical direction. However, a biased voltage distribution caused by a standing wave in the conveying direction, that is, a biased film formation speed in the conveying direction, is easily cancelled by conveying the substrate along the conveying direction. Accordingly, in each film formation compartment, the layout of the plurality of flat application electrodes in the conveying direction improves the homogeneity of the film characteristics regardless of the length in the conveying direction.

Preferably, in the method for manufacturing a thin film solar cell, the distance between the edge of the flat application electrode and the power supply terminal is set to be shorter than λ/2 in the conveying direction.

In this method, standing waves formed in the conveying direction is reduced.

Preferably, the substrate is an iron material having a thickness of 0.05 mm to 0.2 mm and covered by a corrosion-resistant plating coating, and a reflective electrode is arranged on the substrate by superimposing at least one of zinc oxide, indium oxide, and tin oxide on either one of a silver thin film and an aluminum thin film.

In this method, the base material of the substrate is formed from a highly versatile metal that absorbs electrical and thermal biases. Thus, even when a biased voltage distribution occurs in the flat application electrode, electrical and thermal biases applied to the substrate are absorbed. Further, the substrate surface is covered by a corrosion-resistant plating film. Thus, when determining film formation conditions such as the film formation gas type, film formation temperature, and film formation pressure, the range of the film formation conditions may be expanded. Moreover, the substrate is a thin plate using iron, which is highly versatile. This reduces the cost of the thin film solar cell. When the substrate uses a base material of iron and has a thickness of 0.05 mm or greater, wrinkles do not form when unwinding a roll of the substrate. Further, when the substrate uses a base material of iron and has a thickness of 0.2 mm or less, unwinding is smoothly performed. Further, a reflective electrode layer, which is a thin film, is used as the reflective electrode. This reduces the material cost of the reflective electrode, which, in turn, reduces the cost of the thin film solar cell.

Preferably, in the method for manufacturing a thin film solar cell, the forming a power generation layer includes forming a first power generation layer from amorphous silicon germanium, forming a second power generation layer from amorphous silicon germanium, and forming a third power generation layer from amorphous silicon. The first to third power generation layers are sequentially superimposed from the substrate, and a band gap of the first power generation layer is narrower than a band gap of the second power generation layer.

Preferably, in the method for manufacturing a thin film solar cell, the forming a power generation layer includes forming a first power generation layer from microcrystal silicon, forming a second power generation layer from microcrystal silicon, and forming a third power generation layer from amorphous silicon. The first to third power generation layers are sequentially superimposed from the substrate, and the first power generation layer and the second power generation layer amplify voltage.

Preferably, in the method for manufacturing a thin film solar cell, the forming a power generation layer includes forming a first power generation layer from microcrystal silicon, and forming a second power generation layer from amorphous silicon. The first and second power generation layers are sequentially superimposed from the substrate.

Preferably, in the method for manufacturing a thin film solar cell, the forming a power generation layer further includes forming a first power generation layer from microcrystal silicon, forming a second power generation layer from amorphous silicon, and forming a zinc oxide thin film between the first power generation layer and the second power generation layer.

Preferably, in the method for manufacturing a thin film solar cell, the forming the power generation layer further includes forming a first power generation layer from microcrystal silicon, forming a second power generation layer from amorphous silicon, and forming either one of a silicon oxide thin film and a titanium oxide thin film between the first power generation layer and the second power generation layer with a thickness of 10 nm to 100 nm.

Preferably, the method for manufacturing a thin film solar cell further includes bending an end of the substrate in the conveying direction after forming the power generation layer.

In this method, the bending of the end of the substrate increases the mechanical strength of the substrate. In other words, the mechanical strength of the thin film solar cell may be compensated for by the bending of the substrate end. This allows for the substrate to be thinner when the thin film solar cell is manufactured and thereby lowers the cost of the thin film solar cell.

Preferably, in the method for manufacturing a thin film solar cell, a flat ground electrode functioning as a heating source is arranged sandwiching the substrate with the plurality of flat application electrodes, and the substrate is conveyed while maintaining a clearance of 0.05 mm to 1 mm between the flat ground electrode and the substrate.

In this method, the heating efficiency of the substrate is increased and the heat distribution on the substrate becomes homogeneous. Further, mechanical damage of the substrate caused by friction between the substrate and the flat plate electrode is avoided.

A thin film solar cell according to the present invention is manufactured by the manufacturing method described above and includes the substrate formed by an iron substrate having a thickness of 0.05 mm to 0.2 mm and covered by a corrosion-resistant plating coating, a reflective electrode layer superimposed on the substrate, the power generation layer superimposed on the reflective electrode layer, a transparent electrode layer superimposed on the power generation layer, and a protective layer superimposed on the transparent electrode layer.

In this structure, the base material of the substrate is formed from iron having superior thermal conductivity and electric conductivity. Thus, even when a biased voltage distribution occurs in the flat application electrode, electrical and thermal biases applied to the substrate are absorbed. Further, the substrate surface is covered by a corrosion-resistant plating film. Thus, when determining film formation conditions such as the film formation gas type, film formation temperature, and film formation pressure, the range of the film formation conditions may be expanded. Moreover, the substrate is a thin plate using iron, which is highly versatile. This reduces the cost of the thin film solar cell. When the substrate uses a base material of iron and has a thickness of 0.05 mm or greater, wrinkles do not form when unwinding a roll of the substrate. Further, when the substrate uses a base material of iron and has a thickness of 0.2 mm or less, unwinding is smoothly performed.

As described above, the present invention provides an apparatus for manufacturing a thin film solar cell that improves the homogeneity of film characteristics when performing a film formation process on a substrate while unwinding the substrate from a roll, a method for manufacturing the thin film solar cell, and the thin film solar cell.

### BRIEF DESCRIPTION OF THE DRAWINGS

FIG. 1 is a perspective view showing a thin film solar cell of a preferred embodiment;

FIGS. 2A to 2D are cross-sectional diagrams each showing a partial cross-sectional structure of the thin film solar cell;

FIG. 3 is a schematic plan view showing a film formation apparatus of a preferred embodiment;

FIG. 4 is a diagram showing each film formation compartment in a film formation chamber of a first embodiment;

FIG. 5 is a schematic plan view showing an electrode layout in the film formation compartments of the first embodiment;

FIG. 6 is a schematic side view showing an electrode layout in the film formation compartments of the first embodiment;

FIG. 7 is a schematic plan view showing an electrode layout in the film formation compartments of a second embodiment;

FIG. 8 is a schematic side view showing an electrode layout in the film formation compartments of the second embodiment;

FIG. 9 is a diagram showing each film formation compartment in a film formation chamber of a modified example; and

FIG. 10 is a diagram showing the electrode layout in a modified example.

### DETAILED DESCRIPTION OF THE EMBODIMENTS

### First Embodiment

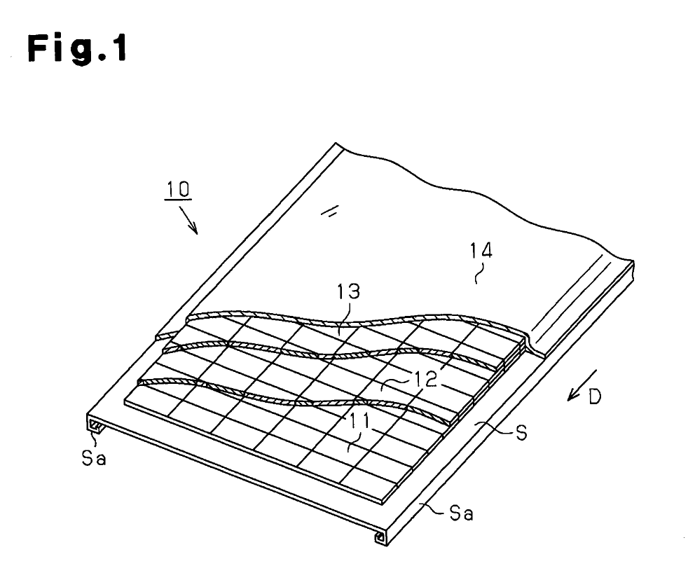

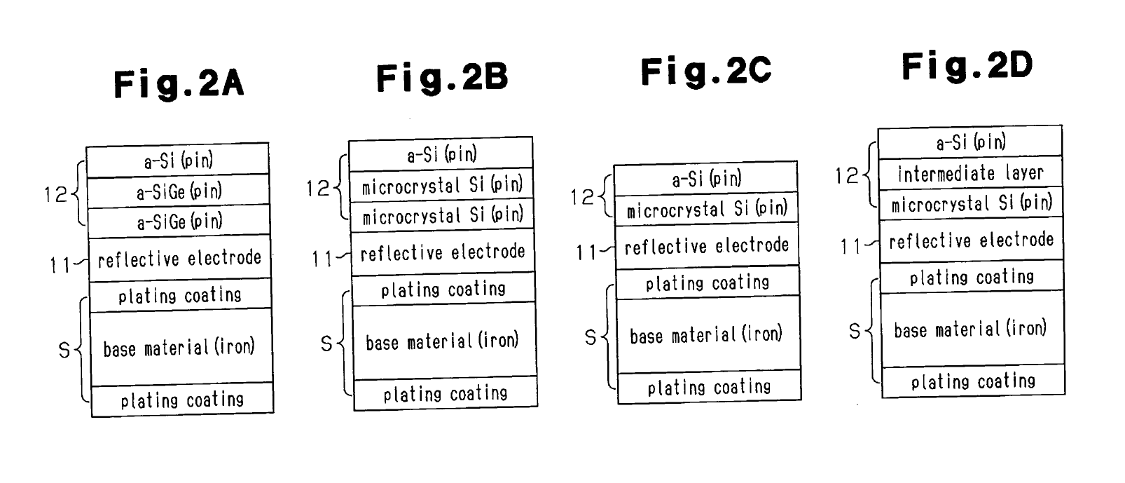

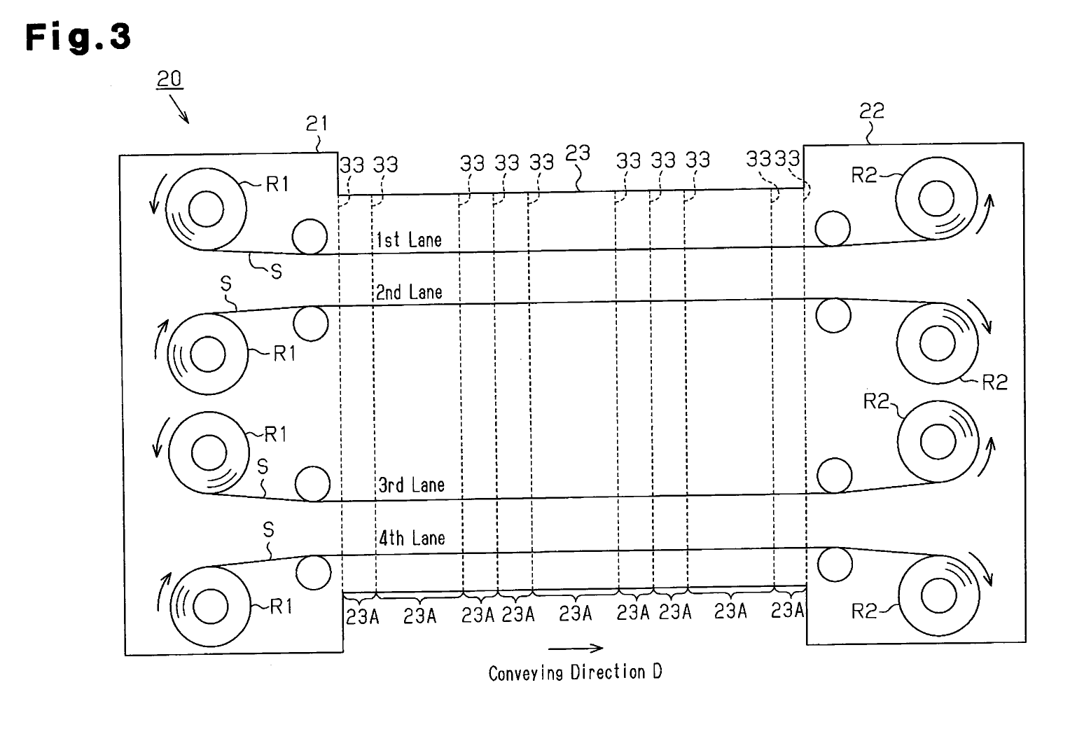

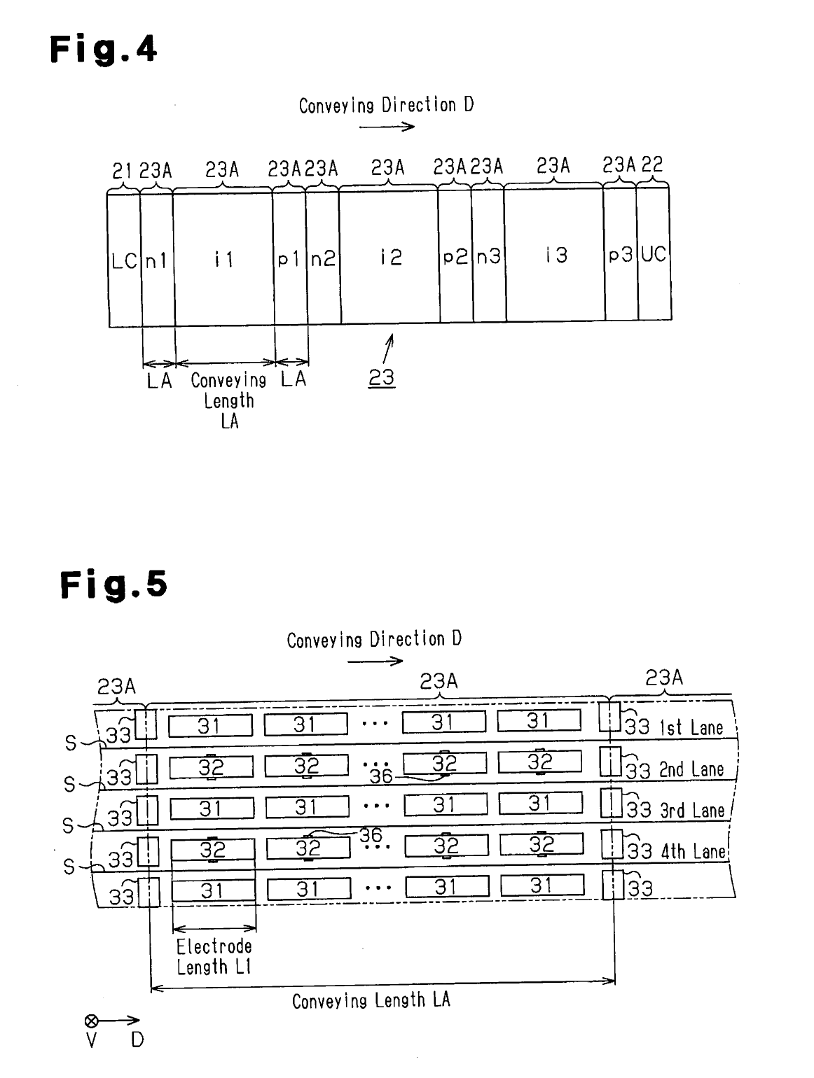

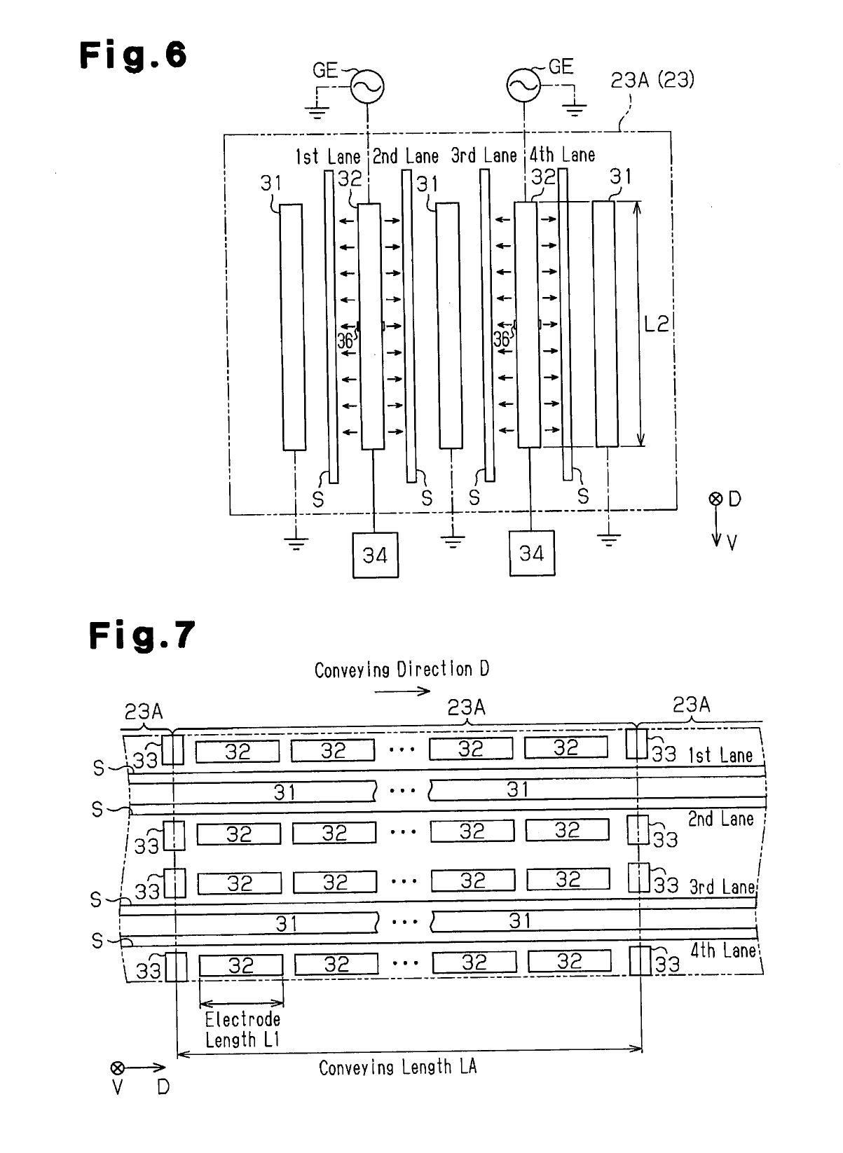

A first embodiment of the present invention will now be described with reference to FIGS. 1 to 6. FIGS. 1 and 2 are diagrams showing the layered structure of a thin film solar cell. FIG. 3 is a schematic diagram showing a film formation apparatus, which serves as an apparatus for manufacturing a thin film solar cell, as viewed in a vertical direction. FIG. 4 is a schematic diagram showing the layout of film formation compartments in a film formation chamber. FIGS. 5 and 6 are schematic diagrams showing the layout of electrodes in the film formation compartments as viewed in the vertical direction and conveying direction.

As shown in FIG. 1, the thin film solar cell 10 includes a reflective electrode layer 11, a power generation layer 12, a transparent electrode layer 13, and a protective layer 14, which are superimposed in order on an upper side (front side) of a metal substrate S. The metal substrate S is a strip of a sheet substrate and is a large substrate of which width in the short axis direction is, for example, one meter. The base material of the substrate used as the metal substrate S is formed from a highly versatile metal that absorbs electrical and thermal biases occurring in the substrate in a manufacturing process, while lowering the cost of the thin film solar cell 10. For example, a substrate of which base material is iron and of which thickness is 0.05 mm or 0.2 mm is used as the substrate. When using metal having a low corrosion resistance such as iron as the base material of the metal substrate S, it is preferred that wet plating using nickel or the like that has high corrosion resistance be performed on the surface of the metal substrate S to cover the metal substrate S with a corrosion-resistant plating coating. Further, when the metal substrate S is formed from iron, it is preferable that the thickness be 0.05 mm or greater so that wrinkles do not form when unwinding a roll of the metal substrate S. It is also preferred that the thickness be 0.2 mm or less so that unwinding is smoothly performed.

Two bent portions Sa, which are bent away from the reflective electrode layer 11 (rear side) and have L-shaped cross-sections, are formed on the two ends of the metal substrate S in the short axis direction. The two bent portions Sa extend throughout the metal substrate S in the longitudinal direction to increase the rigidity of the metal substrate. The bent portion Sa is formed, for example, by bending just one millimeter of the two ends of the metal substrate S in the short axis direction after forming the reflective electrode layer 11 and the power generation layer 12 on the metal substrate S. As a result, the mechanical strength of the metal substrate, which is a thin plate, is increased. This, in turn, improves the mechanical strength of a thin film solar cell 10.

The reflective electrode layer 11 is an electrode layer that receives light transmitted through the power generation layer 12 and reflects the light back to the power generation layer 12. The reflective electrode layer 11 may be, for example, a single-layer electrode formed from silver, zinc oxide, or indium oxide. As another example, the reflective electrode layer 11 may be a layered electrode formed superimposing at least one of zinc oxide, indium oxide, and tin oxide on either one of a silver thin film and an aluminum thin film. Further, when using silver as the reflective electrode layer 11, either one of sputtering and wet plating is performed on the metal substrate S. When using zinc oxide and indium oxide, atmospheric pressure CVD is performed on the metal substrate S. Films of silver, zinc oxide, and indium oxide are formed in this manner. To improve the light enclosure effect in the thin film solar cell 10, it is preferable that the reflective electrode layer 11 have a texture structure.

The power generation layer 12 is a laminated film including a plurality of semiconductor layers of amorphous silicon (a-Si), amorphous silicon germanium (a-SiGe), and the like. Further, the power generation layer 12 forms a unit cell with the so-called pin structure in which an n layer, which is an n-type semiconductor layer, an i layer, which is an i-type semiconductor layer, and a p layer, which is a p-type semiconductor layer, are sequentially superimposed. The power generation layer 12 may have, for example, a tandem structure or triple structure that superimposes a plurality of the unit cells having different spectrums to efficiently absorb light in each wavelength band and perform photoelectric conversion.

More specifically, when the structure of the power generation layer 12 from the metal substrate S is such that it is first power generation layer/second power generation layer/third power generation layer, first power generation layer/second power generation layer, or first power generation layer/intermediate layer/second power generation layer, the laminated structure may be as listed below and shown in FIGS. 2A to 2D.
a-SiGe(pin)/a-SiGe(pin)/a-Si(pin)

The first power generation layer has a higher Ge rate than the second electrode layer and a narrower band gap than the second power generation layer (refer to FIG. 2A).
microcrystal Si(pin)/microcrystal Si(pin)/a-Si(pin)

This first generation layer has a larger grain diameter than the second electrode layer and a narrower band gap than the second power generation layer (refer to FIG. 2B).
microcrystal Si(pin)/a-Si(pin) (refer to FIG. 2C).
microcrystal Si(pin)/intermediate layer/a-Si(pin) (refer to FIG. 2D).

The film thickness of the above-described a-SiGe(pin) may be such that, for example, p-type/i-type/n-type is 10 nm/120 nm/10 nm. The film thickness of the above-described a-Si(pin) may be such that, for example, p-type/i-type/n-type is 10 nm/100 nm/10 nm. The film thickness of the microcrystal Si(pin) may be such that, for example, p-type/i-type/n-type is 10 nm/1000 nm/10 nm. The film formation speed of the microcrystal Si may be changed as required. When using microcrystal a-Si, a larger film thickness than a-Si is required but a higher throughput than a-Si is obtained.

The intermediate layer may be a zinc oxide thin film having a thickness of 1 nm to 70 nm and formed by performing sputtering. Alternatively, the intermediate layer may be either one of an oxide silicon film and a titanium oxide thin film having a thickness of 10 to 100 nm and formed by performing CVD. In particular, when using a silicon oxide film as the intermediate layer, the ratio of oxygen atoms relative to silicon atoms is adjusted to 1 to 2. When using a titanium oxide film, the ratio of oxygen atoms relative to titanium atoms is adjusted to 1 to 2. This allows for the light striking the thin film solar cell 10 to be effectively reflected at either one of the silicon oxide film and titanium oxide film in the long wavelength band of light. As a result, the conversion efficiency of the thin film solar cell 10 is improved.

The protective layer 14 is a resin film that protects the transparent electrode layer 13, the power generation layer 12, and the reflective electrode layer 11 from ambient air. The protective layer 14 may be formed by a transparent resin film of (ethylene-tetrafluoroethylene) fluoropolymer (ETFE) such as FLUON (registered trademark).

As shown in FIG. 3, a film formation apparatus 20 includes an unwinding chamber (LC21), which accommodates four unwinding rolls R1, a winding chamber (UC22), which accommodates four winding rolls R2. The unwinding chamber and winding chamber are connected by a single film formation chamber 23 (power generation layer formation unit) to form a single vacuum tank shared by each chamber. The rolls R1 and R2 form a substrate conveying unit. In the film formation apparatus 20, the four unwinding rolls R1 face toward the four winding rolls R2 on opposite sides of the film formation chamber 23. A single roller pair is formed by two rolls facing toward each other at opposite sides of the film formation chamber 23.

In each of the four roll pairs, the opposing unwinding roll R1 and winding roll R2 are rotated in the directions indicated by the arrows. This unwinds the unwinding roll R1 of metal substrate S, conveys the metal substrate S to the roll R2 at a constant conveying speed while being continuously held upright, and winds the metal substrate S onto the winding roll R2. The conveying paths (first lane to fourth lane) of the metal substrates S for the four roll pairs are parallel to one another. The direction extending along the lanes (sideward direction in FIG. 3) is referred to as the conveying direction D of the metal substrates S.

The film formation chamber 23 is a chamber for forming the power generation layer 12 by performing plasma CVD. Each of the first to fourth lanes include a plurality of film formation compartments 23A defined along the conveying direction D in the film formation chamber 23. The quantity of the film formation compartments 23A conforms to the quantity of the layers described above. The film formation compartments 23A are associated with the semiconductor layers described above so that the laid out order of the film formation compartments 23A in the conveying direction D conforms to the superimposing order of the semiconductor layer.

For example, when the power generation layer 12 has a triple-structure (pin/pin/pin), as shown in FIG. 4, the film formation compartment 23A closest to LC21 is associated with an n1 layer, which is the lowermost semiconductor layer. The film formation compartments 23A from thereon in the conveying direction are sequentially associated with an i1 layer, p1 layer, n2 layer, i2 layer, p2 layer, n3 layer, i3 layer, and p3 layer. The length of each film formation chamber 23A in the conveying direction (conveying length LA) is set based on the film formation time of the associated semiconductor layer and the conveying speed of the metal substrate S. The conveying length LA increases as the film formation time increases. For example, when the film formation time for the n1 layer, i1 layer, and p1 layer are respectively 10 sec, 75 sec, and 10 sec and the conveying speed of the metal substrate S is 0.3 m/sec, the conveying lengths LA of the n1 layer, the i1 layer, and the p1 layer are respectively 3 m (10×0.3), 22.5 m (75×0.3), and 3 m (10×0.3).

As shown in FIG. 5, each lane is sandwiched by a plurality of ground electrodes 31 and a plurality of high frequency electrodes 32 inside each film formation compartment 23A with the ground electrodes 31 and high frequency electrodes 32 being alternately arranged. Further, a plurality of gas seals 33 are arranged so as to sandwich each lane at the starting point and ending point in the conveying direction D inside each film formation compartment. Each of the plurality of gas seals blasts gas toward the metal substrate S in the proximate lane. This forms a gas curtain between adjacent film formation compartments 23A and partitions the interior of the film formation chamber 23 in a non-contact manner. The gas used for the gas curtain may be an inert gas or a film formation gas that is commonly used between the adjacent film formation chambers 23A.

The plurality of ground electrodes 31, which are arranged at equal intervals in the conveying direction D, are flat ground electrodes connected to a ground potential and are each formed to have the shape of a tetragonal plate with a surface extending in the conveying direction D and the vertical direction V. Each ground electrode 31 includes a heating source (not shown) to heat the metal substrate S. The heating source is driven to heat the metal substrate S that is proximate to the ground electrode 31 to a predetermined film formation temperature. That is, each ground electrode 31 forms a ground potential in the corresponding film formation compartment 23A and functions as a heater for heating the metal substrate S. The clearance between the metal substrate S and the ground electrodes 31 in the conveying process is held at, for example, 0.05 mm to 1 mm. As long as the clearance is narrow and less than 1 mm, even when a versatile pressure of 0.5 to 1 Torr is applied to the film formation compartment 23A, a relatively high coefficient of heat transfer is obtained in the pressure region. Further, heat is easily transferred from the ground electrode 31 to the metal substrate S. Moreover, even when the metal substrate S is in the conveying process, the heating efficiency of the metal substrate S is improved and the heat distribution in the metal substrate S becomes homogeneous. When the clearance is set to the lower limit of 0.05 mm or greater, an excessive increase in the capacitance component between the metal substrate S and the ground electrode 31 is suppressed. Further, when generating plasma in the film formation compartment 23A, impedance matching is easily performed. Moreover, the film quality under stable plasma becomes homogeneous while avoiding damages of the metal substrate S caused by friction between the metal substrate S and the ground electrode 31.

The plurality of high frequency electrodes 32, which are arranged at equal intervals in the conveying direction D facing toward the ground electrodes 31, are flat application electrodes connected to a high frequency power supply GE (refer to FIG. 6) and are each formed to have the shape of a tetragonal plate with a surface extending in the conveying direction D and the vertical direction V. In each high frequency electrode 32, a terminal (power supply terminal 36), which is connected to the high frequency power supply GE, is formed at the central part with respect to the conveying direction D and the vertical direction V, namely, the central part in an electrode surface of the high frequency electrode 32. The power supply terminal 36 of the high frequency electrode 32 is supplied with high frequency power in the VHF band from the high frequency power supply GE. The range of 30 MHz to 300 MHz may be used as the VHF band. More preferably, the range of 40 MHz to 80 MHz may be used. When the frequency of the high frequency power becomes high, the plasma density in the film formation compartments 23A becomes high. This increases the film formation speed. When the plasma density in the film formation compartments 23A is excessively high, the energy of the ions striking the metal substrate S and the film formation compartments 23A would be high. Such striking of the ions would result in the metal substrate S and film formation compartments 23A being vulnerable to plasma damages. Further, when the plasma density in the film formation compartments 23A become excessively high, the homogeneity of the density would be difficult to maintain. Thus, the homogeneity in the film characteristics of the metal substrate S may easily be lost. Accordingly, the frequency of the high frequency power used for the high frequency electrodes 32 is selected from the VHF band in accordance with various conditions such as the film formation gas, the film formation pressure, and the film formation temperature to increase the throughput with a complementary relationship with the plasma density.

A first electrode length L1, which is the length of the high frequency electrodes 32 in the conveying direction, is set based on the wavelength of the high frequency power. When the wavelength is represented by λ, (1 m to 10 m), the distance between the edge of the electrode surface, which is the open end of the transmission path, and the power supply terminal 36 in the conveying direction D is set to be shorter than λ/2. Further, a second electrode length L2 (refer to FIG. 6), which is the length of the high frequency electrodes 32 in the vertical direction V, is also set based on the wavelength of the high frequency power. The distance between the edge of the electrode surface, which is the open end of the transmission path, and the power supply terminal 36 in the vertical direction V is set to be shorter than λ/4.

Due to such electrode size, when the high frequency power in the VHF band is supplied to the high frequency electrodes 32, the formation of a standing wave in the conveying direction D is reduced at the electrode surfaces. The formation of a standing wave in the vertical direction V is also reduced at the electrode surface. A biased voltage distribution caused by a standing wave in the conveying direction D, that is, a biased film formation speed in the conveying direction is apt to being canceled by conveying the metal substrate S along the conveying direction D. A biased voltage distribution caused by a standing wave in the conveying direction D, that is, a biased film formation speed in the vertical direction V, is transferred as a film quality distribution throughout the width of the metal substrate S in the vertical direction V regardless of the metal substrate S being conveyed. Thus, by setting the upper limit of the distance between the edge of the electrode surface and the power supply terminal 36 in the vertical direction V to be λ/4, the homogeneity of the film quality distribution in the vertical direction V of the metal substrate may be increased. Further, the distance between the edge of the electrode surface and the power supply terminal 36 has an upper limit (λ/4) in the vertical direction V that is smaller than the upper limit (λ/2) of the same in the conveying direction D. This ensures that a biased voltage distribution caused by a standing wave in the vertical direction V of the high frequency electrode 32 is more suppressed than that in the conveying direction D. Thus, a biased film quality distribution caused by a standing wave is suppressed even when the conveying length LA of the film formation compartments 23A is significantly longer than the wavelength of the high frequency power, namely λ, to obtain the film formation time.

As shown in FIG. 6, each high frequency electrode 32 is connected to a gas supply unit 34, which supplies the film formation gas. When the gas supply unit 34 supplies the high frequency electrode 32 with film formation gas, as shown by the arrows in FIG. 6, the film formation gas is sent from the high frequency electrode 32 toward the two ground electrodes 31 sandwiching the high frequency electrode 32. In this manner, the high frequency electrode 32 supplies high frequency power to the corresponding film formation compartment 23A and functions as a shower head for the two ground electrodes 31 sandwiching the high frequency electrode 32. Although not shown in the drawings, preferably, the high frequency electrode 32 has a surface including a plurality of elliptic recesses, and a film formation portion opens in the bottom surface of each recess with a width that is smaller than the shorter side of the recess (for example, a hole having a smaller diameter than the recess). In this case, film formation gas is ejected from the open part of the film formation gas supply portion in each recess. This homogeneously and stably generates high-density plasma in the plane of the high frequency electrode 32 and efficiently decomposes the film formation gas. Accordingly, the homogeneity of the film characteristics is increased, and high-speed film formation becomes possible.

When forming the p layer (a-Si), SiH4/H2/B2H6 may be used as the film formation gas. When forming the i layer (a-Si), SiH4/H2 may be used as the film formation gas. When forming the n layer (a-Si), SiH4/H2/PH3 may be used as the film formation gas. When using these film formation gases, H2 may be selected as the gas for forming the gas curtain.

When rotation of the four roll pairs convey the metal sheet S along each lane, in each film formation compartment 23A, the heating source for each ground electrode 31 is driven to heat the metal substrate S to a predetermined temperature. Further, the gas supply unit 34 is driven to supply the film formation gas via the high frequency electrodes 32 to the metal substrate S, and the high frequency power supply GE is driven to generate plasma with the film formation gas between the high frequency electrodes 32 and the ground electrodes 31. In this state, a biased voltage distribution in the electrode surfaces of the high frequency electrodes 32 subtly occurs. Thus, a homogeneous film formation process is performed on the overall metal substrate S that passes between the high frequency electrodes 32 and the ground electrodes 31.

The film formation apparatus of the first embodiment has the advantages described below.

(1) The distance between the edge of each high frequency electrode 32 and the power supply terminal 36 is shorter than λ/2 in the conveying direction D and shorter than λ/4 in the vertical direction V. This reduces the formation of a standing wave in the conveying direction D at the high frequency electrode 32, and formation of a standing wave in the vertical direction V at the high frequency electrode 32 is further reduced. In each film formation compartment 23A, the high frequency electrodes 32 are laid out along the conveying direction D. This suppresses voltage distribution in the conveying direction D and the vertical direction V regardless of the conveying length LA. As a result, when performing a film formation process on the metal substrate S wound around the unwinding roll R1, the homogeneity of the film characteristics is increased.

(2) The film formation process may be performed on two metal substrates S with a single high frequency electrode 32. Thus, the structure of the film formation compartments 23A may be simplified from the aspect of improving the productivity of the thin film solar cell 10 with the plurality of lanes.

(3) The film formation compartments 23A are partitioned from one another in a non-contact manner by gas curtains. Thus, the film formation process may be performed continuously throughout the entire film formation chamber 23 without stopping the unwinding of the metal substrate S.

(4) The metal substrate S, of which base material is iron and thickness is 0.05 mm to 0.2 mm, is used as the substrate for the thin film solar cell 10. The metal substrate S, which is the film formation subject, is formed by a material having superior electrical and thermal conductivity. Further, the metal substrate S is covered by a corrosion-resistant plating coating. Thus, when setting the film formation conditions, such as the film formation gas type, film formation temperature, and film formation pressure, the range of the film formation conditions may be increased. Moreover, the metal substrate is a thin plate of iron, which has high versatility, and thereby allows for reduction in the cost of the thin film solar cell 10. Further, the iron plate used as the base material has a thickness of 0.05 mm or greater so that wrinkles do no form when unwinding a roll of the metal substrate S. Moreover, the base material of iron has a thickness of 0.2 mm or less so that unwinding of the metal substrate S may be smoothly performed.

(5) The bent portions Sa are formed at the ends of the metal substrate S in the conveying direction D. Thus, even when the base material of the thin film solar cell 10, namely, the metal substrate S, is thin, the mechanical strength of the thin film solar cell 10 may be increased. Further, the thickness of the metal substrate S may be decreased in the process for manufacturing the thin film solar cell 10. This allows for reduction in the cost of the thin film solar cell 10.

(6) A clearance is maintained in the conveying process between the metal substrate S and the ground electrode 31. Thus, even in the conveying process of the metal substrate S, the metal substrate S is prevented from being damaged by friction that occurs between the metal substrate S and the ground electrodes 31. Additionally, the clearance is maintained at 0.05 mm to 1 mm. This increases the heating efficiency of the metal substrate S while making the heat distribution on the metal substrate 31 homogenous.

Further, by decreasing the clearance, the metal substrate S and the ground electrodes 31 increases capacitance and facilitates coupling. Thus, by maintaining the clearance at 0.05 mm to 1 mm, high frequency current propagated from plasma easily reaches the ground electrodes.

### Second Embodiment

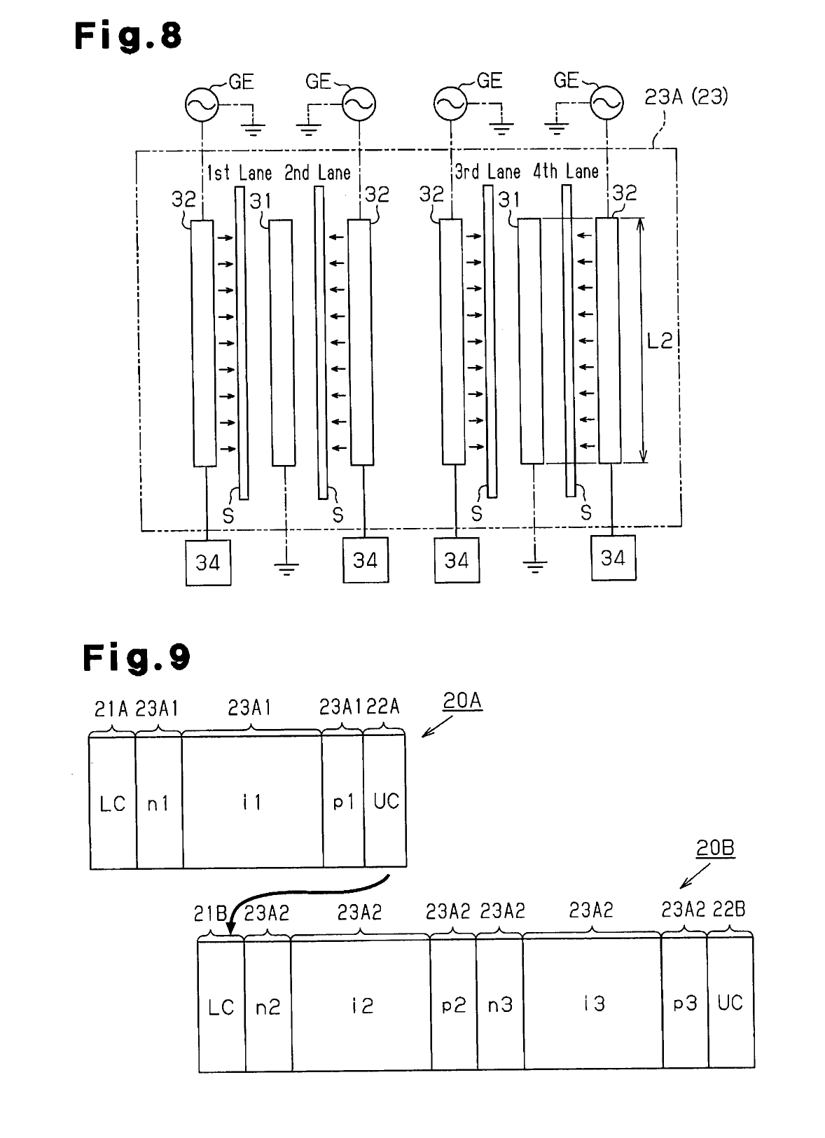

A second embodiment of the present invention will now be discussed with reference to FIGS. 7 and 8. In the second embodiment, the electrode layout of the first embodiment is changed. The changes will be described below in detail. FIGS. 7 and 8 are schematic diagrams showing the layout of electrodes in film formation compartments as viewed in the vertical direction and in the conveying direction.

As shown in FIG. 7, a ground electrode 31 extending continuously in the conveying direction D is arranged in a film formation compartment 23A between a first lane and second lane and between a third lane and a fourth lane. Further, a plurality of ground electrodes 32 are arranged at equal intervals along the conveying direction D so as to sandwich the first lane with the corresponding ground electrode 31 and to sandwich the second lane with the corresponding ground electrode 31. A plurality of gas seals 33 are arranged to sandwich the metal substrates S with the corresponding ground electrode 31 and blast gas toward the metal substrate S in the proximate lane. This forms a gas curtain between adjacent film formation compartments 23A and partitions the interior of the film formation chamber 23 in a non-contact manner.

In the same manner as the first embodiment, each high frequency electrode 23 has a length in the conveying direction D and a length in the vertical direction V respectively set as the first electrode length L1 and the second electrode length L2. Thus, when high frequency power in the VHF band is supplied to the high frequency electrodes 32, formation of a standing wave in the conveying direction at the electrode surfaces is reduced, and formation of a standing wave in the vertical direction V at the electrode surfaces is further reduced. Thus, in the same manner as the first embodiment, a biased film quality distribution caused by a standing wave is suppressed even when the conveying length of the film formation compartment 23A is significantly longer than λ, which is the wavelength of the high frequency power, to ensure the film formation time.

When rotation of the four roll pairs convey the metal sheet S along each lane, in each film formation compartment 23A, the gas supply unit 34 is driven to supply the film formation gas via the high frequency electrodes 32 to the metal substrate S, and the high frequency power supply GE is driven to generate plasma with the film formation gas between the high frequency electrodes 32 and the ground electrode 31. In this state, a biased voltage distribution in the electrode surfaces of the high frequency electrodes 32 subtly occurs. Thus, a homogeneous film formation process is performed on the overall metal substrate S that passes between the high frequency electrodes 32 and the ground electrode 31.

The film formation apparatus of the second embodiment has the advantages described below.

(7) The film formation process may be performed on two metal substrates S with a single ground electrode 31. Thus, the structure of the film formation compartments 23A may be simplified from the aspect of improving the productivity of the thin film solar cell 10 with the plurality of lanes.

(8) The plurality of high frequency electrodes 32, which are adjacent to one another in the conveying direction D, are associated with the single ground electrode 31, which extends continuously in the conveying direction. In this manner, the plurality of high frequency electrodes 32 commonly share the single ground electrode 31. This obtains homogeneous film characteristics with a further simplified structure.

(9) The high frequency electrodes 32 are arranged in correspondence with each metal substrate S. This increases the degree of freedom when setting the range of the film formation conditions for each high frequency electrode 32.

The above-discussed embodiments may be modified as described below.

In the first embodiment, a single high frequency electrode 32 performs the film formation process on two metal substrates S. However, in FIG. 6, the film formation process may be performed by using the ground electrode 31 in lieu of the high frequency electrodes 32 and using the high frequency electrode 32 in lieu of the ground electrode 31. In this structure, the film formation process is performed on two metal substrates S with a single ground electrode. This simplifies the structure of the film formation compartment 23A from the aspect of improving the productivity of the thin film solar cell 10 with a plurality of lanes.

In the first embodiment, a single ground electrode 31, which is a flat ground electrode, is arranged in correspondence with a single high frequency electrode 32, which is a flat application electrode. However, in the same manner as the second embodiment, a single ground electrode 31 extending continuously in the conveying direction D may be arranged in correspondence with a plurality of high frequency electrodes 32 that are adjacent to one another in the conveying direction. With this structure, the first embodiment may obtain homogeneous film characteristics with a further simplified structure.

In the above-discussed embodiments, the interior of the film formation chamber 23 is partitioned by gas curtains to form the plurality of film formation compartments 23A. The embodiments are not limited to such a structure. As long as the transfer (crosstalk) of film formation gas between adjacent film formation compartments is suppressed, any structure that partitions the interior of the film formation chamber 23 may be used. For example, partition walls that contact the metal substrate S may be used. When forming the film formation compartments 23A through physical contact between the metal substrates S and partition walls in such a manner, the structure of the substrate conveying unit must be changed. Further, whenever forming a film formation compartment 23A, rotation of the rolls must be stopped to perform the film formation process for each layer.

In the above-discussed embodiment, each film formation compartment 23A forms a film formation area commonly shared by every lane. However, the film formation compartment 23A may be formed independently for each lane. In this structure, the size of the film formation compartment may be changed for each lane. Thus, different power generation layers 12 may be formed with a single film formation apparatus 20. This is advantageous when forming many types of power generation layers 12.

In the above-discussed embodiment, the distance between the edge of the high frequency electrode 32 and the power supply terminal 36 is shorter than λ/2 in the conveying direction D and shorter than λ/4 in the vertical direction D. However, the embodiments are not limited to such a structure, and the distance between the edge of the high frequency electrode 32 and the power supply terminal 36 may be shorter than λ/4 in the plane of the electrode surface. This makes it difficult for a standing wave to be formed throughout the electrode surface of the high frequency electrode and further ensures that a biased voltage distribution is suppressed. Thus, the homogeneity in the film characteristics is further improved when performing the film formation process on the metal substrate S, which is wound around the unwinding roll R1.

In the above-discussed embodiments, the high frequency electrodes 32 have the shapes of tetragonal flat plates. Instead, the high frequency electrodes 32 may have, for example, the shape of an elliptic plate. Further, it is only required that the distance between the edge of the high frequency electrode 32 and the power supply unit 36 be shorter than λ/2 in the conveying direction D and shorter than λ/4 in the vertical direction D.

In the above-discussed embodiments, the distance between the edge of the high frequency electrode 32 and the power supply terminal 36 is shorter than λ/4 in the vertical direction D. Instead, when the main surface of the substrate serving as the film formation subject is inclined relative to the vertical direction V during conveying or when the electrode surface of the high frequency electrode 32 is inclined relative to the vertical direction V, the distance between the edge of the high frequency electrode 32 and the power supply terminal 36 may be shorter than λ/4 in the planar direction of the main surface or the planar direction of the electrode surface, which is orthogonal to the conveying direction D.

In the above-discussed embodiments, the substrate conveying unit includes four roll pairs. However, the substrate conveying unit may include, for example, just a single roll pair. In this case, each of the two rolls is rotated so that the substrate unwound from one roll is conveyed to the other roll and wound around the other roll.

In the above-discussed embodiments, the single film formation chamber 23, which is the power generation layer formation unit, forms the power generation layer 12. However, the embodiments are not limited in such a manner, and two or more film formation chambers 23 may form the power generation layer 12. For example, as shown in FIG. 9, a first film formation apparatus 20A, which includes a plurality of first film formation compartments 23A1, and a second film formation apparatus 20B, which includes a plurality of second film formation compartments 23A2, may be used to form a triple structure power generation layer. When forming a triple structure power generation layer, the first film formation apparatus 20A forms a first pin structure. Then, the second film formation apparatus 20B forms second and third pin structures.

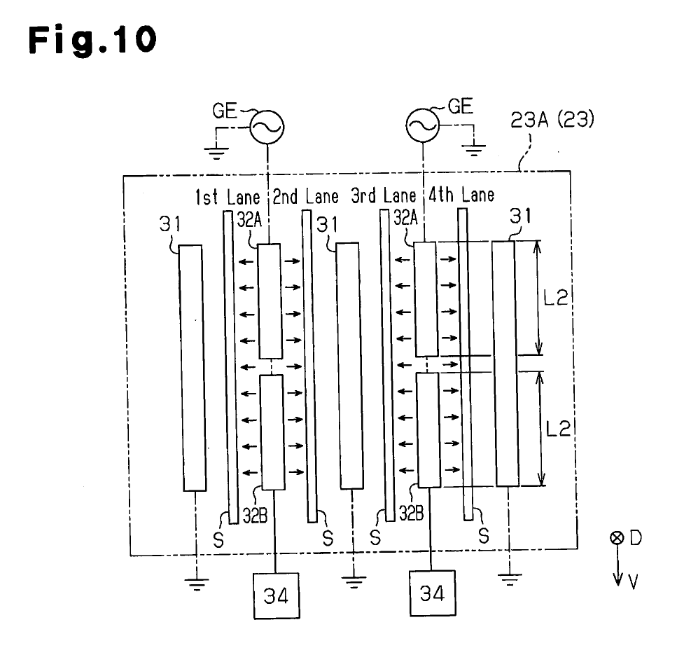

In the above-discussed embodiments, the plurality of high frequency electrodes 32 may be arranged in the vertical direction V, which is the widthwise direction of the metal substrate S, in addition to the conveying direction D. For example, as shown in FIG. 10, a plurality of first flat application electrodes 32A, which are laid out along the conveying direction D facing toward the substrate S, and a plurality of second flat application electrodes 32B, which are laid out along the conveying direction facing toward the substrate S, may be arranged spaced apart from one another in the vertical direction (direction orthogonal to the conveying direction D). In this structure, even when the widths (electrode length L2) of the electrodes 32A and 32B in the vertical direction V becomes short due to a process using a shorter wavelength, the two electrodes 32A and 32B prevent a state in which there are not enough electrodes for the width of the substrate S.

In the above-discussed embodiment, the substrate is embodied in a metal substrate. However, the substrate may be embodied in a high heat resistant resin substrate of polyamide or the like.

1. An apparatus for manufacturing a thin film solar cell, the apparatus comprising:
a substrate conveying unit including a pair of rolls arranged in a vacuum tank, in which the pair of rolls are rotated to convey a substrate from one of the rolls to the other one of the rolls; and
a power generation layer formation unit including a plurality of film formation compartments partitioned along a conveying direction of the substrate between the pair of rolls, in which each of the plurality of film formation compartments forms a semiconductor layer on the substrate to form a power generation layer that is a laminated body of a plurality of semiconductor layers;
wherein each of the plurality of film formation compartments includes a plurality of flat application electrodes laid out along the conveying direction facing toward the substrate, the plurality of flat application electrodes each include a power supply terminal supplied with high frequency power in a VHF band, and when the wavelength of the high frequency power is represented by λ, distance between an edge of the flat application electrode and the power supply terminal is shorter than λ/4 in a direction orthogonal to the conveying direction.

2. The apparatus for manufacturing a thin film solar cell according to claim 1, wherein the distance between the edge of the flat application electrode and the power supply terminal is shorter than λ/2 in the conveying direction.

3. The apparatus for manufacturing a thin film solar cell according to claim 1, wherein the distance between the edge of the flat application electrode and the power supply terminal is shorter than λ/4 in a plane of the flat application electrode that includes the conveying direction.

4. The apparatus for manufacturing a thin film solar cell according to claim 1, wherein the substrate conveying unit includes adjacent first and second roll pairs, each being the pair of rolls;
the power generation layer formation unit including a film formation compartment commonly shared by the first and second roll pairs; and
the commonly shared film formation compartment includes a flat ground electrode sandwiching the substrate with the plurality of flat application electrodes, in which the plurality of flat application electrodes or the flat ground electrode is arranged between a pair of substrates that are conveyed by the first and second rolls and shared by the two substrates.

5. The apparatus for manufacturing a thin film solar cell according to claim 1, wherein the plurality of film formation compartments are partitioned by gas curtains between the pair of rollers; and
the substrate conveying unit continuously rotates the pair of rollers until the substrate on the one of the rollers is wound around the other one of the rolls.

6. The apparatus for manufacturing a thin film solar cell according to claim 1, further comprising a single flat plate ground electrode facing toward the plurality of flat application electrodes that are adjacent to one another in the conveying direction and commonly shared by the plurality of flat application electrodes.

7. The apparatus for manufacturing a thin film solar cell according to claim 1, wherein each of the plurality of film formation compartments includes a plurality of second flat application electrodes laid out along the conveying direction and facing toward the substrate, and the plurality of second flat application electrodes are spaced apart from the plurality of flat application electrodes in a direction orthogonal to the conveying direction.

8. A method for manufacturing a thin film solar cell, the method comprising:
rotating a pair of rolls arranged in a vacuum tank to convey a substrate from one of the rolls to the other one of the rolls; and
forming a power generation layer that is a laminated body of a plurality of semiconductor layers in a plurality of film formation compartments partitioned along a conveying direction of the substrate between the pair of rolls while conveying the substrate;
wherein the forming a power generation layer includes applying high frequency power in a VHF band to a plurality of flat application electrodes laid out along the conveying direction facing toward the substrate, the high frequency power is supplied to a power supply terminal arranged in each of the plurality of flat application electrodes, and when the wavelength of the high frequency power is represented by λ, distance between an edge of the flat application electrode and the power supply terminal is set to be shorter than λ/4 in a direction orthogonal to the conveying direction.

9. The method for manufacturing a thin film solar cell according to claim 8, wherein the distance between the edge of the flat application electrode and the power supply terminal is set to be shorter than λ/2 in the conveying direction.

10. The method for manufacturing a thin film solar cell according to claim 8, wherein the substrate is an iron material having a thickness of 0.05 mm to 0.2 mm and covered by a corrosion-resistant plating coating, and a reflective electrode is arranged on the substrate by superimposing at least one of zinc oxide, indium oxide, and tin oxide on either one of a silver thin film and an aluminum thin film.

11. The method for manufacturing a thin film solar cell according to claim 8, wherein the forming a power generation layer includes:
forming a first power generation layer from amorphous silicon germanium;
forming a second power generation layer from amorphous silicon germanium; and
forming a third power generation layer from amorphous silicon; and
the first to third power generation layers are sequentially superimposed from the substrate, and a band gap of the first power generation layer is narrower than a band gap of the second power generation layer.

12. The method for manufacturing a thin film solar cell according to claim 8, wherein the forming a power generation layer includes:
forming a first power generation layer from microcrystal silicon;
forming a second power generation layer from microcrystal silicon; and
forming a third power generation layer from amorphous silicon; and
the first to third power generation layers are sequentially superimposed from the substrate, and the first power generation layer and the second power generation layer amplify voltage.

13. The method for manufacturing a thin film solar cell according to claim 8, wherein the forming a power generation layer includes:
forming a first power generation layer from microcrystal silicon; and
forming a second power generation layer from amorphous silicon; and
the first and second power generation layers are sequentially superimposed from the substrate.

14. The method for manufacturing a thin film solar cell according to claim 13, wherein the forming a power generation layer further includes:
forming a zinc oxide thin film between the first power generation layer and the second power generation layer.

15. The method for manufacturing a thin film solar cell according to claim 13, wherein the forming the power generation layer further includes:
forming either one of a silicon oxide thin film and a titanium oxide thin film between the first power generation layer and the second power generation layer with a thickness of 10 nm to 100 nm.

16. The method for manufacturing a thin film solar cell according to claim 8, further comprising:
bending an end of the substrate in the conveying direction after forming the power generation layer.

17. The method for manufacturing a thin film solar cell according to claim 8, wherein a flat ground electrode functioning as a heating source is arranged sandwiching the substrate with the plurality of flat application electrodes, and the substrate is conveyed while maintaining a clearance of 0.05 mm to 1 mm between the flat ground electrode and the substrate.

18. A thin film solar cell manufactured by the manufacturing method according to claim 8, the thin film solar cell comprising:
the substrate formed by an iron substrate having a thickness of 0.05 mm to 0.2 mm and covered by a corrosion-resistant plating coating;
a reflective electrode layer superimposed on the substrate;
the power generation layer superimposed on the reflective electrode layer;
a transparent electrode layer superimposed on the power generation layer; and
a protective layer superimposed on the transparent electrode layer.

19. The apparatus for manufacturing a thin film solar cell according to claim 2, wherein the distance between the edge of the flat application electrode and the power supply terminal is shorter than λ/4 in a plane of the flat application electrode that includes the conveying direction.

20. The apparatus for manufacturing a thin film solar cell according to claim 2, wherein the substrate conveying unit includes adjacent first and second roll pairs, each being the pair of rolls;
the power generation layer formation unit including a film formation compartment commonly shared by the first and second roll pairs; and
the commonly shared film formation compartment includes a flat ground electrode sandwiching the substrate with the plurality of flat application electrodes, in which the plurality of flat application electrodes or the flat ground electrode is arranged between a pair of substrates that are conveyed by the first and second rolls and shared by the two substrates.
